(19) United States
(12) Patent Application Publication
(10) Pub. No.: US 2025/0071933 A1
(43) Pub. Date: Feb. 27, 2025

(54) Electronics Cabinet with Improved Air Flow

(71) Applicant: Climate Conditioning Company, Inc., Louisville, KY (US)

(72) Inventors: Matthew Graham, Louisville, KY (US); Jeremy Allen, Louisville, KY (US); Matthew Abbott, LaGrange, KY (US)

(21) Appl. No.: 18/455,337

(22) Filed: Aug. 24, 2023

(51) Int. Cl. H05K 7/20

(52) U.S. Cl. CPC H05K 7/20145

(57) ABSTRACT

An electronics cabinet with improved air flow including ductwork with inlet(s) and outlet(s) approximately ninety-degrees from one another, the ductwork being substantially vertically centered within the electronics cabinet. The outlet(s) of the ductwork may open into a cavity defined by a front door and an electronics rack of the electronics cabinet. Forced air convected into the cavity may build pressure sufficient for circulation of the forced air from the cavity through the electronics and/or electronics rack and towards a rear of the electronics cabinet. The forced air may eventually be expelled out of, and/or recirculated within, the electronics cabinet.

### BACKGROUND

Electronics cabinets are used for a variety of purposes including storage, maintenance, and cooling of electronic equipment. Electronic equipment typically generates and/or releases ambient or operational heat. Performance of electronic equipment may be affected by a variety of factors, including temperature. Accordingly, maintaining electronic equipment within a temperature range can maintain and/or increase performance of the electronic equipment.

### SUMMARY

Implementations set forth herein relate to an electronics cabinet with improved air flow. The electronics cabinet permits improved air flow into, about, around, and/or from electronic equipment inside the cabinet. In some implementations, improved air flow results from air, which is in part moved by an air conditioning (AC) unit, traveling through ductwork connecting the air conditioning unit with a cavity formed between a front door of the cabinet and an electronics rack adjacent to the front door.

In some implementations, ductwork follows an approximately 90-degree curve from entrance orifices adjacent to the air conditioning unit to termination orifice(s) adjacent to the electronics rack. In some implementations, the termination orifice(s) may be approximately vertically and horizontally centered in and/or on the electronics rack and open towards the front door, permitting air to exit the ductwork into the cavity via the termination orifice. Air may be pushed into the cavity by the air conditioning unit, forcing air into, about, around, and/or from electronics stored in, on, and/or around the electronics rack. Forced air may modify an existing temperature of the electronics inside the electronics cabinet due to temperature differences existing between the forced air and the electronics.

In various implementations, an electronics cabinet may be provided that includes: a housing that includes a plurality of surfaces, including a top surface, a bottom surface, two opposing side surfaces, a front surface, and a rear surface, a cooling device mounted to one of the opposing side surfaces included in the housing; an air distribution conduit that fluidly couples the cooling device with an interior of the housing, wherein the air distribution conduit is shaped to direct air from the cooling device mounted to the one of the opposing side surfaces to an exit orifice of the air distribution conduit that is located adjacent to an interior face of the front surface.

In various implementations, the electronics cabinet may include an electronics rack extending between the two opposing side surfaces, the electronics rack being separated from the front surface by a cavity between the front surface and a front surface facing plane of the electronics rack that is parallel with the front surface, the cavity permitting air expelled from the exit orifice to permeate through the cavity towards the rear and opposing side surfaces.

In various implementations, the exit orifice is approximately vertically centered between the top surface and the bottom surface.

In various implementations, the electronics cabinet may further include: a first damper on the front surface permitting air located exterior of the electronics cabinet to convect through the first damper to the interior of the housing; and a second damper on the back surface permitting air located in the interior of the housing to convect through the second damper to the exterior the electronics cabinet. In various implementations, the first damper may be located a first distance from the bottom surface, and the second damper may be located a second distance from the bottom surface, the second distance being greater than the first distance. In various implementations, the first damper and/or the second damper may interface with one or more ventilation fans.

In various implementations, the cooling device may detachably interface with the one of the opposing side surfaces. In various implementations, the electronics cabinet may include a bottom L-shaped bracket on the one of the opposing side surfaces, wherein the bottom L-shaped bracket detachably secures the cooling device with one of the opposing side surfaces included in the housing. In various implementations, the bottom L-shaped bracket may be a French cleat.

In various implementations, the front and rear surfaces may be displaceable doors. In various implementations, the exit orifice of the air distribution conduit may be approximately horizontally centered between the opposing side surfaces.

In a related aspect, an alternative electronics cabinet may include: a housing that includes a roof, a floor, two opposing side walls, a front door, and a rear door, one or more air conditioning units mounted to one of the opposing side walls included in the housing; an electronics rack extending between the two opposing side walls and including one or more slots for receiving electronic equipment; and ductwork that fluidly couples the one or more air conditioning units with an interior of the housing, wherein the ductwork is routed through the frame to direct air from the air conditioning units to an opening of the ductwork that empties into a cavity defined between an interior face of the front door and a front door facing plan of the electronics rack, the cavity permitting air expelled from the opening to permeate through the cavity towards the rear door and opposing side walls.

In various implementations, the opening of the ductwork may be vertically centered nearly equidistant from the roof and the floor.

In various implementations, the electronics cabinet may include a first damper on the front door permitting air located exterior of the electronics cabinet to convect through the first damper to the interior of the housing; and a second damper on the back surface permitting air located in the interior of the housing to convect through the second damper to a the exterior the electronics cabinet. In various implementations, the first damper may be located a first distance from the floor, and the second damper may be located a greater distance from the floor, and wherein the first damper and/or the second damper interface with one or more ventilation fans. In various implementations, the first damper convects cooler air exterior the electronics cabinet to a location in the interior of the housing and the second damper convects hotter air in the interior the electronics cabinet to exterior the electronics cabinet.

In various implementations, the electronics cabinet may include a bottom L-shaped bracket, wherein the bottom L-shaped bracket detachably secures the air conditioning units with one of the opposing side walls included in the housing. In various implementations, the ductwork may be routed along and/or about a 90 degree angle from the side wall to the front door. In various implementations, the opening of the ductwork may be approximately horizontally centered between the opposing side walls.

### BRIEF DESCRIPTION OF THE DRAWINGS

FIG. 1 illustrates a front top perspective view of the cabinet. The front door is open, and electronics are present in the electronics rack slots.

FIG. 2 illustrates a rear bottom perspective view of the cabinet. The front door is open.

FIG. 3 illustrates a front direct view of the cabinet. The front door is open, and electronics are not in the electronics rack slots.

FIG. 4 illustrates a rear direct view. The front door is open, and the AC unit is removed.

FIG. 5 illustrates a left side direct view. The front door is open.

FIG. 6 illustrates a right side direct view. The front door is closed, and the AC unit is removed-exposing ductwork entrance openings.

FIG. 7 illustrates a top direct view. The front door is open.

FIG. 8 illustrates a bottom direct view. The front door is open.

FIG. 9 illustrates a top direct cross-sectional view-exposing the ductwork.

FIG. 10 illustrates a front top perspective view. The AC unit is displaced from the electronics cabinet.

FIG. 10A illustrates a zoomed in perspective view of a bottom portion of the AC and a bottom bracket with which the bottom portion of the AC unit is capable of interfacing.

FIG. 11 illustrates a front top perspective view having ductwork depicted with solid lines and other features of the electronics cabinet depicted with broken lines.

FIG. 11A illustrates a front top perspective view having the cavity depicted with solid lines and other features of the electronics cabinet depicted with broken lines.

FIG. 12 illustrates a rear bottom perspective view having ductwork depicted with solid lines and other features of the electronics cabinet depicted with broken lines.

FIG. 13 illustrates a front direct view having ductwork depicted with solid lines and other features of the electronics cabinet depicted with broken lines.

FIG. 14 illustrates a rear direct view having ductwork depicted with solid lines and other features of the electronics cabinet depicted with broken lines.

FIG. 15 illustrates a left side direct view having ductwork depicted with solid lines and other features of the electronics cabinet depicted with broken lines.

FIG. 16 illustrates a right side direct view having ductwork depicted with solid lines and other features of the electronics cabinet depicted with broken lines.

FIG. 17 illustrates a top direct view having ductwork depicted with solid lines and other features of the electronics cabinet depicted with broken lines.

FIG. 18 illustrates a bottom direct view having ductwork depicted with solid lines and other features of the electronics cabinet depicted with broken lines.

FIG. 19 illustrates a method for operating the electronics cabinet.

### DETAILED DESCRIPTION

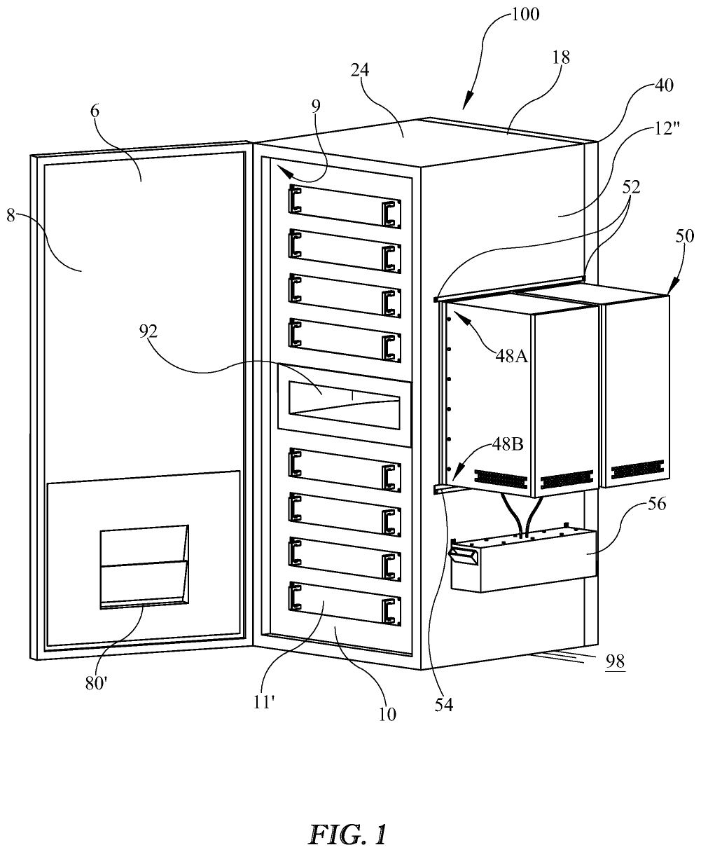

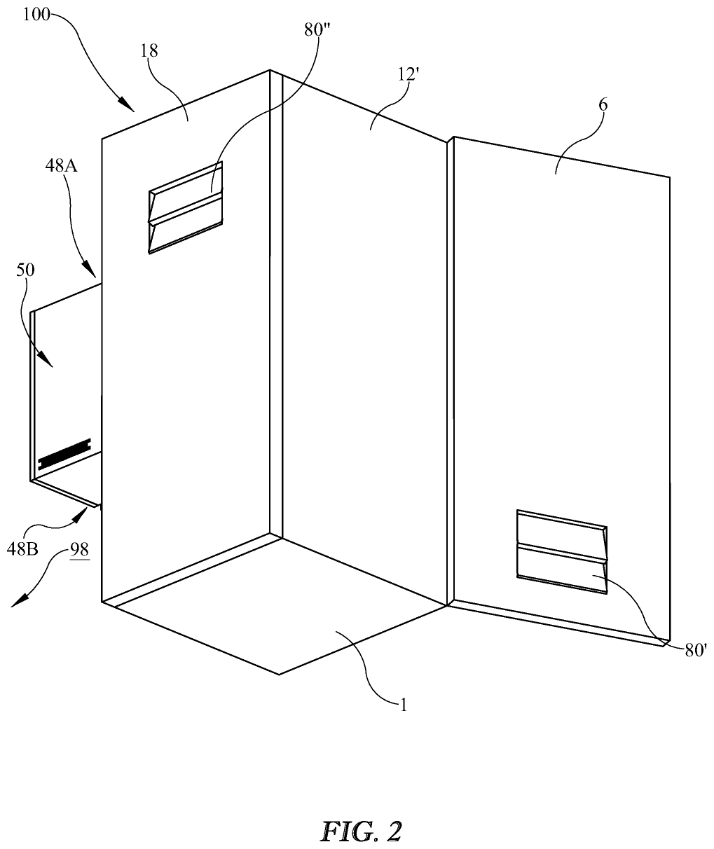

FIG. 1 and FIG. 2 illustrate an electronics cabinet 100 configured with selected aspects of the present disclosure. Referring to FIGS. 1-2, as well as to other figures, the electronics cabinet 100 includes frame 40 (synonymous herein with housing 40) a bottom surface 1 (synonymous herein with floor 1), front surface 6 (synonymous herein with front door 6), two opposing side surfaces 12′ and 12″ (synonymous herein with a first side wall 12′ and second side wall 12″, and/or opposing side walls 12′/12″), a rear surface 18 (synonymous herein with rear door), and a top surface 24 (synonymous herein with roof 24).

An air conditioning (AC) unit 50 may be detachably interfaced with the electronics cabinet 100. The AC unit 50 may also detachably interface with, and/or include, a condensate evaporator 56 for evaporation of condensation that is not evaporated by the AC unit 50. The AC unit 50 may be mounted to electronics cabinet 100 using, for example, a bottom bracket 54 and/or one or more top bolts 52. For example, the AC unit 50 may sit on and/or in, and/or be supported by, bottom bracket 54, which may be statically or displaceably attached to an opposing sidewall 12″. Subsequent to interfacing with bottom bracket 54 attached to the opposing sidewall 12″, the AC unit 50 may be substantially flush with the opposing side wall 12″ of the electronics cabinet 100, and the AC unit 50 may be secured to electronics cabinet 100 using the top bolts 52. The top bolts 52 may displaceably or statically secure an elevated portion of the AC unit 50 to the opposing side wall 12″, the elevated portion being located at a higher elevation relative to a lower portion of the AC unit 50 substantially adjacent to the bottom support bracket 54. The example of FIG. 1 depicts top bolts 52 as interfacing with the opposing side wall 12″ and the AC unit 50.

The AC unit 50 may regulate temperature within and/or about the electronics cabinet 100. This may impact performance of electronic equipment 11′ located in and/or about electronics rack 10. When the front door 6 is closed, the electronics rack 10 and the front door 6 are adjacent. However, as shown in FIG. 1, the electronics rack 10 may be slightly recessed into the electronics cabinet 100, leaving a cavity 9 between the electronics rack 10 and the front door 6.

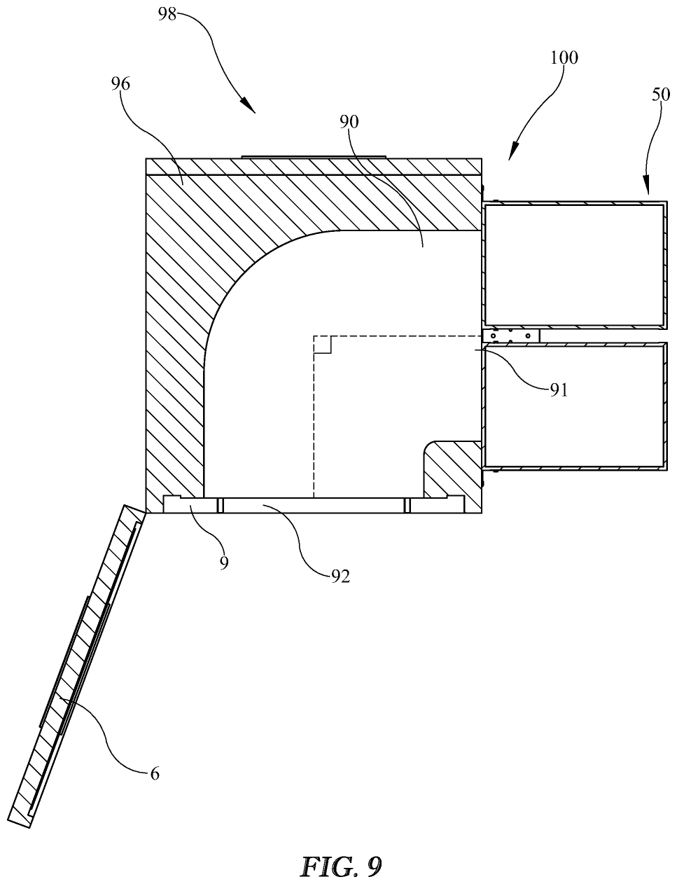

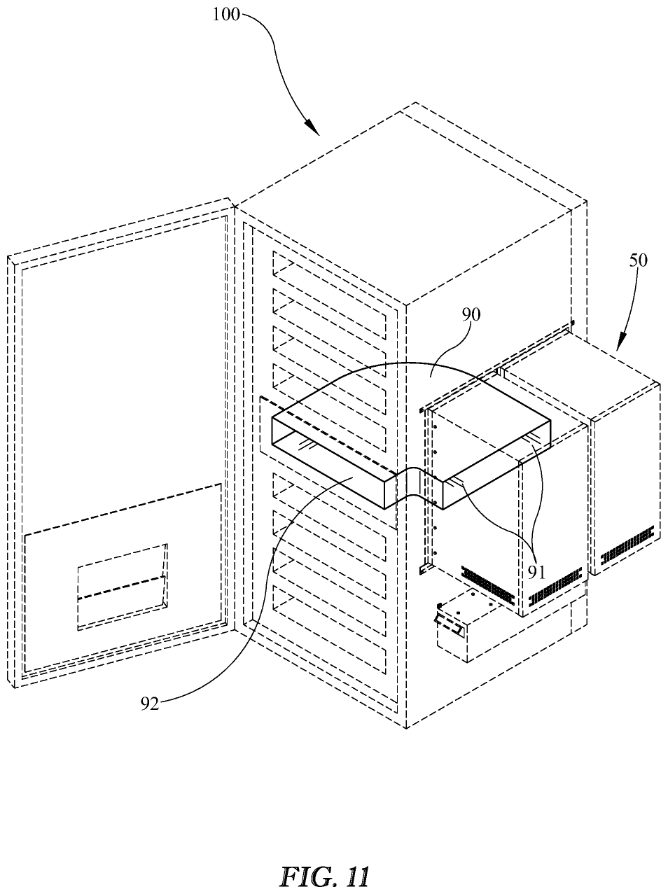

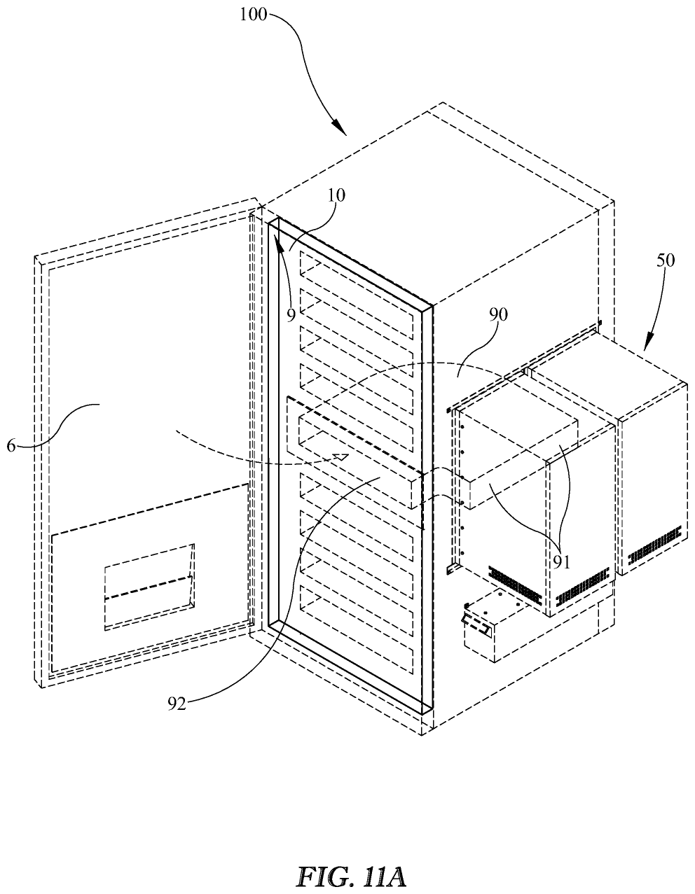

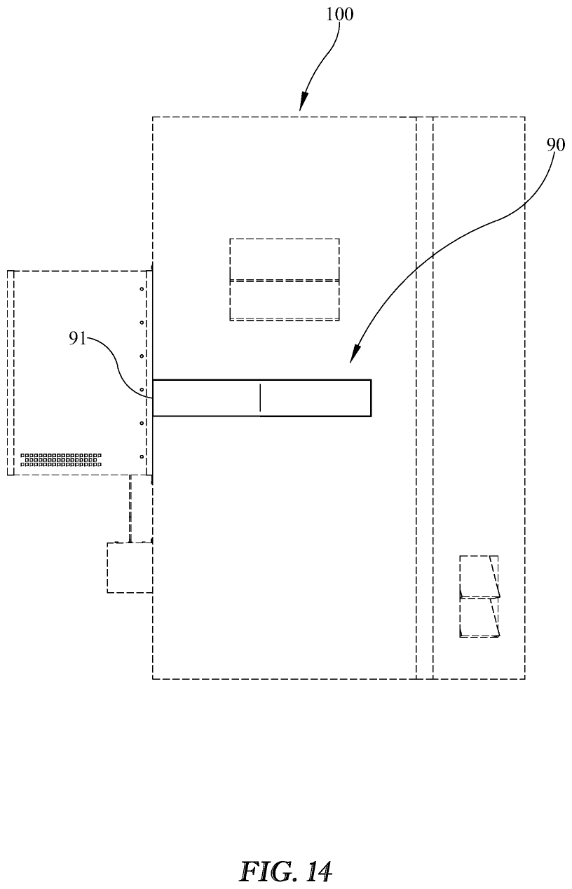

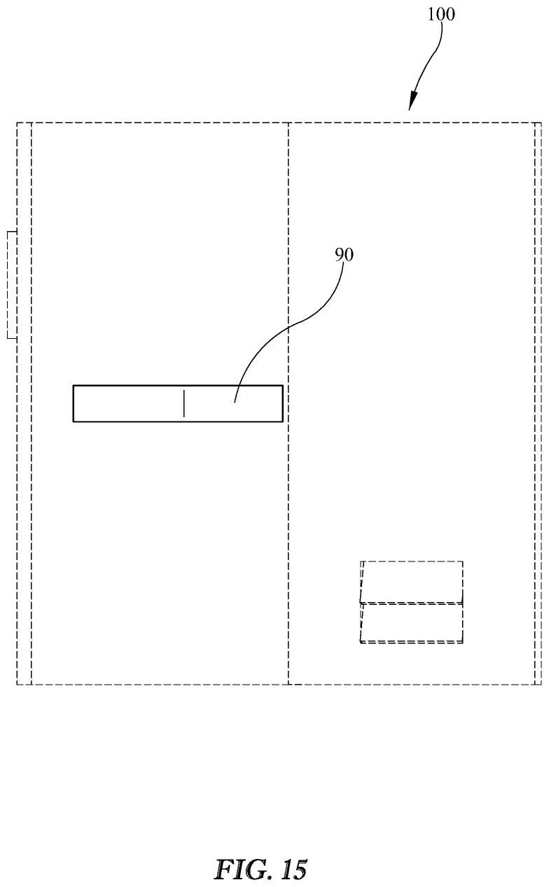

The electronics rack 10 includes an exit orifice 92 from which air moved by the AC unit 50 through ductwork 90 (depicted in FIGS. 9-18) exits the ductwork 90 into the cavity 9 between the front door 6 and the electronics rack 10. Cavity 9 may be defined by one or more first planes parallel with the electronics rack 10, and one or more second planes parallel with front door 6 (while front door 6 is oriented in a closed position), and one or more planes perpendicularly extending from edges of the first plane towards the second plane. FIG. 11A non-limitingly depicts exemplary edges of the first and/or second planes defining the cavity 9 in solid lines. When the front door 6 is closed, air entering the cavity 9 may be dispersed onto, around, through, and/or about the electronics rack 10. For example, while the front door 6 is closed and when AC unit 50 runs continuously, air may be continuously exhausted from the exit orifice 92 into cavity 9. Continuous exhaustion of air into the cavity 9 may disperse air in front of, through, around, and about the electronics rack 10. For instance, air dispersed into cavity 9 may first fill the cavity 9 and thus be dispersed over the electronics rack 10, and subsequently may move through and/or around the electronics rack 10 towards the rear door 18 of the electronics cabinet 100. The air produced by the AC unit 50 at a first instant may have a lower ambient temperature than air circulated past electronic equipment 11′ at a later instant, and/or air not produced and/or not affected by the AC unit 50. Accordingly, movement of air from the AC unit 50 through ductwork 90, into cavity 9, and through and/or about electronics rack 10 may result in lower ambient temperatures throughout the electronics cabinet 100, including the electronics rack 10.

The AC unit 50 may be supplemented by an auxiliary system for movement of air. As depicted in FIG. 1, the front door 6 may be equipped with a damper 80′. Hot air rises and it is therefore consequent that cooler air is frequently ambiently located at a lower elevation relative to hotter air. Accordingly, damper 80′ may be automatically or manually opened to permit cooler air from exterior 98 the electronics cabinet 100 to enter the electronics cabinet 100. In some implementations, one or more fans (not depicted) may be provided to facilitate circulation of air throughout the electronics cabinet 100. For example, in some implementations, when damper 80′ is opened sufficiently to permit air flow therethrough, a fan may pull air from an exterior 98 of the electronics cabinet 100 into the interior 96 of the electronics cabinet 100, specifically into the cavity 9. In other implementations, no fan may be employed.

In some implementations, damper 80′ may close by default due to gravitational force and may open in response to air circulation through damper 80′ exerting a perpendicular and/or opposite circulation force overcoming the gravitational force. The air circulation may be responsive to a pressure change inside the cabinet 100 caused by circulating cooler air interior 96 the cabinet 100 and exhausting hotter air exterior 98 the cabinet 100. Additionally or alternatively, in some implementations, air circulation may be responsive to a fan (not depicted) forcibly circulating air through damper 80′.

FIG. 2 illustrates a rear bottom view of the electronics cabinet 100. The floor 1 and rear door 18 of the electronics cabinet 100 are clearly depicted in FIG. 2. The floor 1 of the electronics cabinet 100 may be flat as depicted or contoured for frictional security and/or to prevent direct contact with ground below the electronics cabinet 100.

As discussed previously, in some implementations, the AC unit 50 may be supplemented by an auxiliary system for the movement of air. Like damper 80′, damper 80″ may facilitate the movement of air. However, due to the previously discussed qualities of air-including temperature-damper 80″ is located at a higher elevation than damper 80′, as depicted in FIG. 2, to facilitate movement of hotter air located inside 96 the electronics cabinet 100 to outside 98 the electronics cabinet 100. For example, damper 80″ may be automatically or manually opened to permit air flow. In some (but not all) implementations, a fan (not depicted) may push hot air, which has risen to an elevation inside 96 the electronics cabinet 100, to an area exterior 98 the electronics cabinet 100.

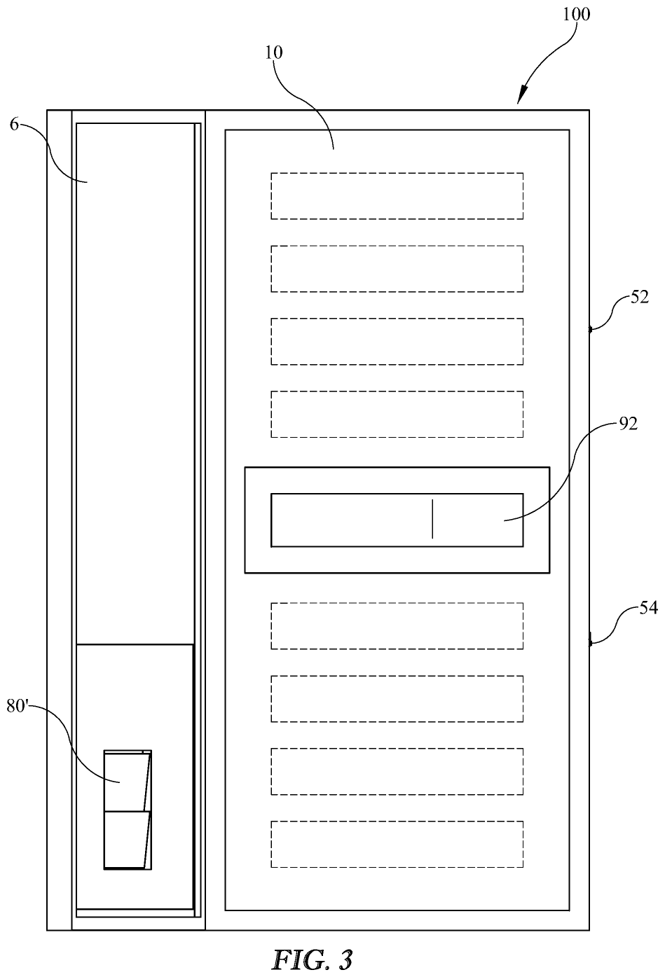

FIG. 3 illustrates a front direct view of the electronics cabinet 100. The front door 6 is opened revealing the electronics rack 10. As indicated by broken lines, the electronics rack 10 may be shaped, sized, and/or contoured to account for factors, such as airflow and/or electronic equipment. For example, the electronics rack 10 may include one or more blanking panels of varying sizes. Accordingly, the electronic rack 10 depicted in FIG. 3 is non-limiting. FIG. 3 depicts electronics cabinet 100 as being currently detached from the AC unit 50. The top bolts 52 and bottom bracket 54, or portions thereof, may remain interfaced with the electronics cabinet 100 when the AC unit 50 is detached.

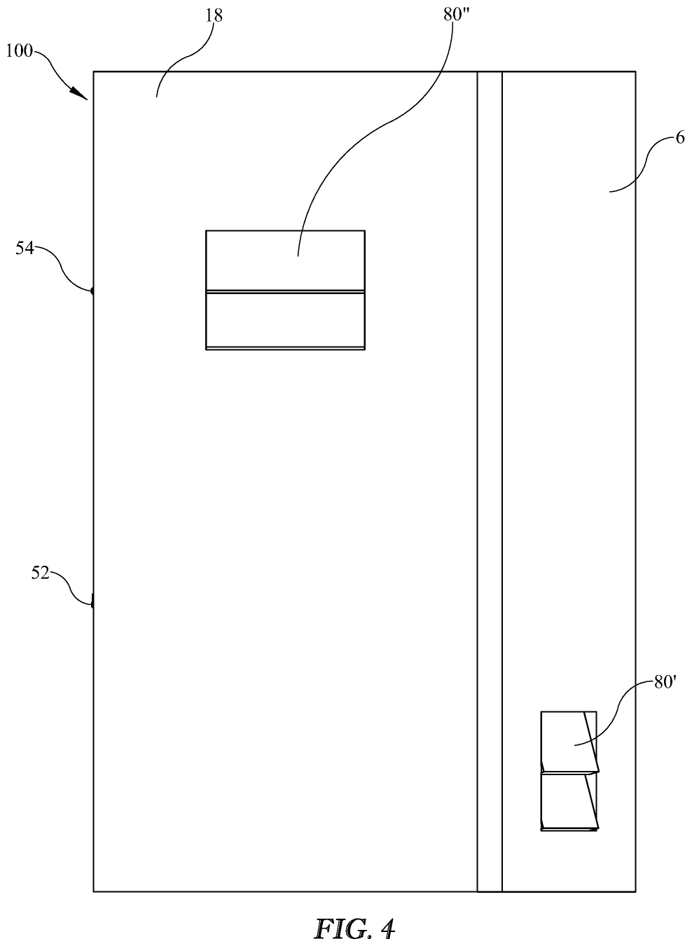

FIG. 4 illustrates a rear direct view of the electronics cabinet 100. The AC unit 50, like the depiction of FIG. 3, remains detached. The front door 6 is open and the rear door 18 is closed. Located on, in, around, and/or about the rear door 18 is damper 80″.

As noted previously, an auxiliary system for the movement of air may use dampers 80′ and 80″ located on, in, and/or about front door 6 and rear door 18′ respectively. Accordingly, front door 6 may include a damper 80′ at a lower height from the floor 1 than damper 80″ included on the rear door 18. Put another way, damper 80′ included with front door 6 may be a greater distance from floor 1 than damper 80″ included with rear door 18. Distances between the dampers 80′/80″ can affect air circulation throughout the electronics cabinet 100. For example, the distances may permit cooler ambient air which may be located at a lower elevation of exterior 98 the electronics cabinet 100 to enter the electronics cabinet 100 at the front door 6, which can aid in circulation of cool air in, about, and/or around the electronics rack 10—and further, the distances may permit hotter ambient air, which has a tendency to rise, which may be located interior 96 the electronics cabinet 100 to be expelled exterior 98 the electronics cabinet 100.

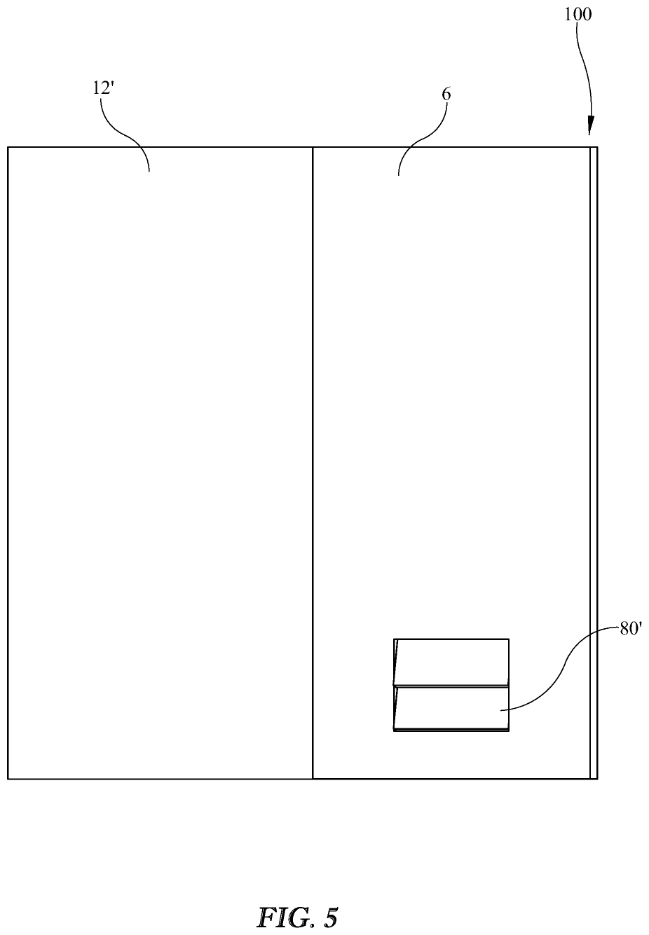

FIG. 5 illustrates a left side direct view of the electronics cabinet 100. The front door 6 is depicted as being open. FIG. 5 depicts the left opposing sidewall 12′ exterior as not interfacing with other objects, except at edges with other surfaces. Symmetries inherent in the electronics cabinet 100 depicted herein would permit modifications enabling the AC unit 50 and accompanying ductwork 90 to be rotated, flipped, and/or otherwise modified such that features of the right opposing sidewall 12″ could be present on the left opposing sidewall 12′. For example, the AC unit 50 could be mounted on left opposing sidewall 12′ instead.

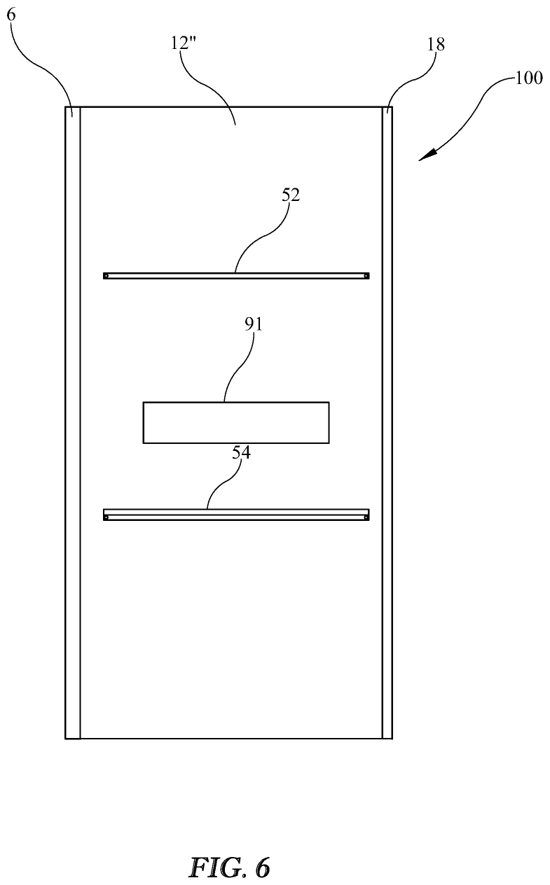

FIG. 6 illustrates a right side direct view of the electronics cabinet 100. The front door 6 is closed. In this depiction, the top bolts 52 and bottom bracket 54 remain interfaced with the electronics cabinet 100 despite AC unit 50 being detached. However, in some instances either or both of top bolts 52 and/or bottom bracket 54 may also be detached from the electronics cabinet 100. Further, ductwork 90 is clearly depicted in FIG. 6. While particular depictions herein example an AC unit 50 including a single cold air exhaust, and ductwork 90 having a single entrance orifice 91 to receive cold air from the AC units' 50 cold air exhausts, this is not meant to be limiting. A greater number of entrance orifice(s) 91 and/or cold air exhaust(s) could be used, depending on a particular style of AC unit(s) 50 interfacing with the electronics cabinet 100.

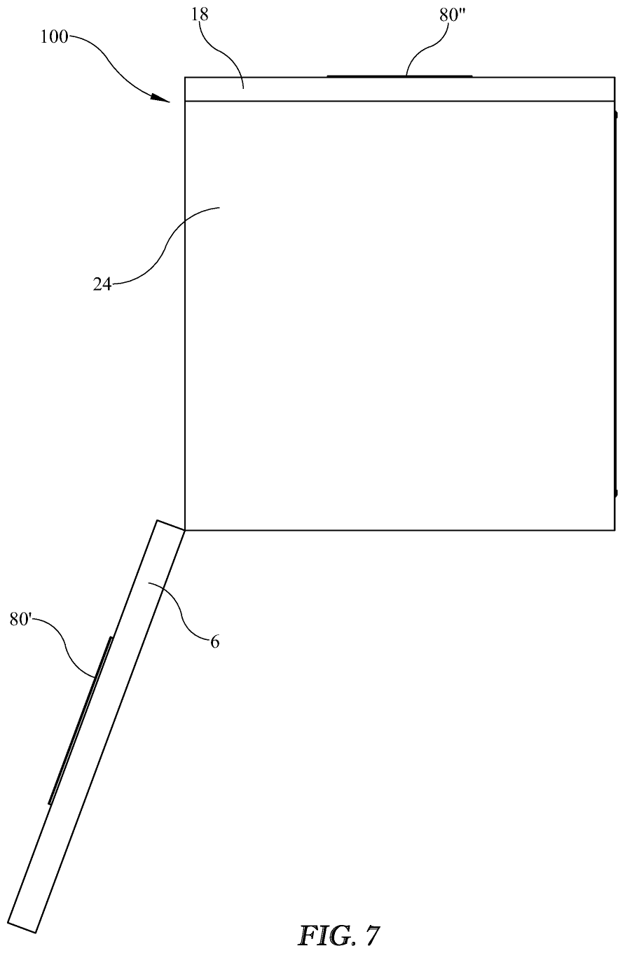

FIG. 7 illustrates a top direct view of the electronics cabinet 100 with the front door 6 open. As depicted herein, the roof 24 exterior of the electronics cabinet 100 may be flat and/or bare. However, this is not meant to be limiting and the roof 24 could interface with components and/or be contoured. For example, the roof 24 could include a damper or a fan. Additionally, the roof 24 could feature one or more slopes. Moreover, in some implementations, electronics cabinets 100 may be stacked on top of one another and/or adjacent to one another, and the roof 24 may incorporate components for securing additional electronics cabinets 100 stacked on and/or adjacent therewith, such as grips, brackets, straps, reinforcement equipment, etc.,

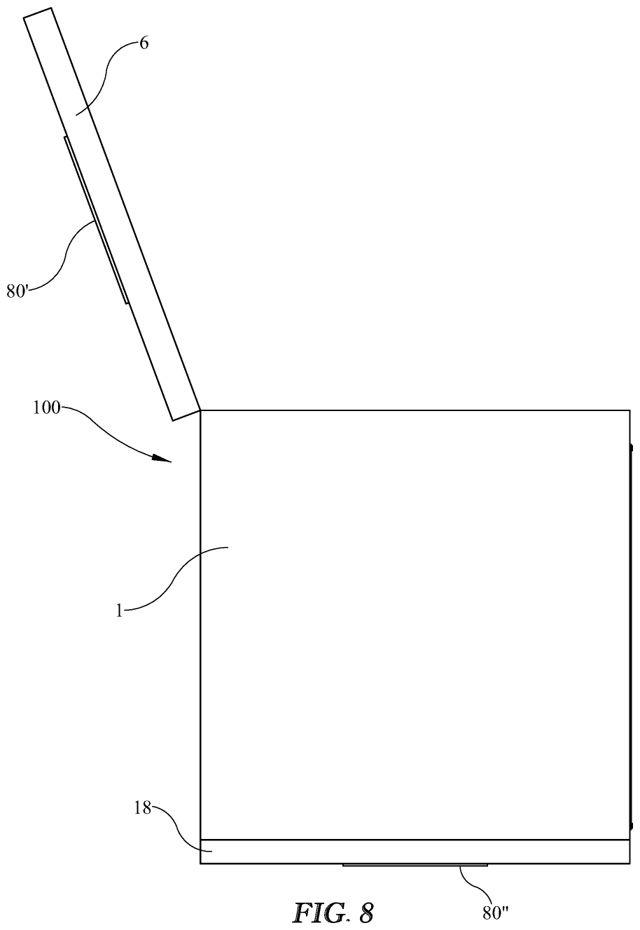

FIG. 8 illustrates a bottom direct view of the electronics cabinet 100 with the front door 6 open. As depicted herein, the floor 1 exterior of the electronics cabinet 100 may be flat and/or bare, similar to the roof 24. However, this is not meant to be limiting, and the floor 1 could interface with components and/or be contoured. For example, the floor 1 could include grips, spacers, or reinforcement equipment. Moreover, as mentioned previously, electronics cabinets 100 may be stacked, and in such instances, dampers and/or fans may be included in floor 1 to, for example, dissipate heat from an electronics cabinet 100 at lower elevation.

FIG. 9 illustrates a cross-sectional top view of the electronics cabinet 100. The front door 6 is open and the AC unit 50 is attached. Ductwork 90 is clearly depicted. As discussed previously, the ductwork 90 permits airflow of air from the AC unit 50 to the cavity 9 between the front door 6 (when closed) and the electronics rack 10. As depicted, the ductwork 90 follows a substantially 90-degree curve from the entrance orifice 91 to the exit orifice 92. The ductwork 90 may be contoured to reduce acute edges which could result in turbulence affecting air circulating through the ductwork 90. The ductwork 90 may also be contoured to reduce obtuse angles in some locations to reduce materials and surface drag affecting air circulating through the ductwork 90. The depiction of FIG. 9 illustrates each entrance orifice 91 being connected to the ductwork 90, and the ductwork 90 having a termination at the exit orifice 92.

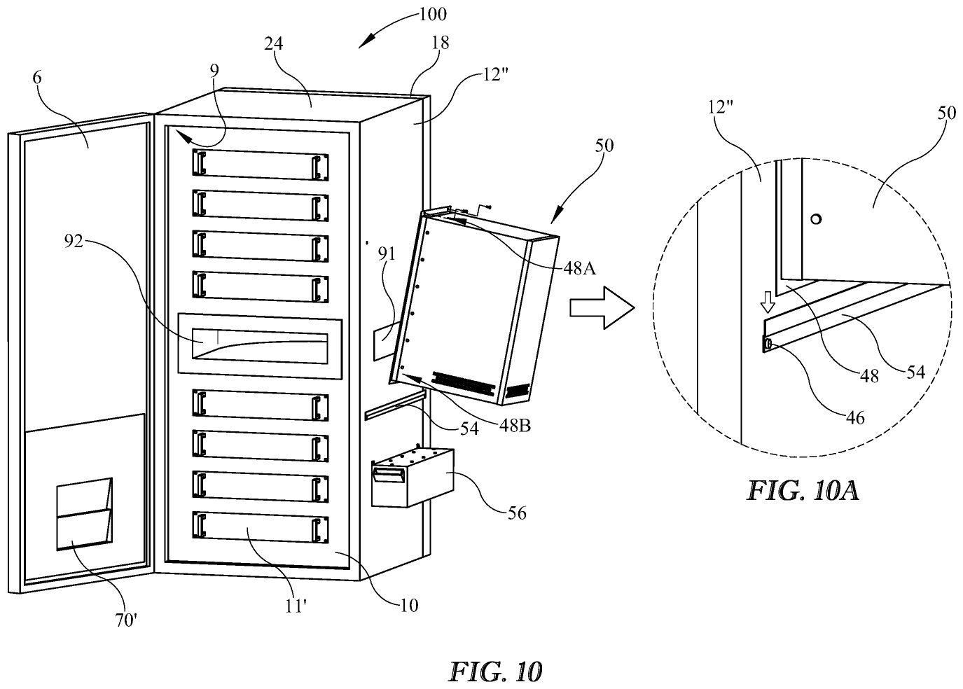

FIG. 10 illustrates a front top perspective view of the electronics cabinet 100. Front door 6 is opened, revealing electronics rack 10, electronic equipment 11′, and exit orifice 92. Cavity 9 would be apparent if front door 6 were closed. FIG. 10 further illustrates the AC unit 50 detached from the electronics cabinet 100. As discussed previously, the top bolts 52 and/or the bottom bracket 54 may in some embodiments be detachable from the electronics cabinet 100. FIG. 10 depicts the top bolts 52 being detached from the electronics cabinet 100 while the AC unit 50 is detached.

FIG. 10A further depicts how AC unit 50 may interface with bottom bracket 54. A portion 48A of the AC unit 50 may interface with the top bolts 52 and the electronics cabinet 100. A portion 48B of the AC unit 50 may interface with the bottom bracket 54 and electronics cabinet 100. For example, the portion 48B of the AC unit 50 may be wedged and/or otherwise secured between the bottom bracket 54 and the electronics cabinet 100.

In some implementations, the portion 48B of the AC unit 50 may be secured subsequent to the bottom bracket 54 being fastenably tightened to the electronics cabinet 100, such as when screws and/or bolts 46 securely connect the bottom bracket 54 with the electronics cabinet 100. In other implementations, the portion 48B of the AC unit 50 may be secured subsequent to being inserted into the bottom bracket 54. For example, the portion 48B of the AC unit 50 and the bottom bracket 54 may interface in a French Cleat configuration, such that the frictional forces between the AC unit 50, bottom bracket 54, and/or electronics cabinet 100 secure the portion 48B of the AC unit into an interfaced position between the bottom bracket 54 and the electronics cabinet 100. A French Cleat interface is not necessarily limited to the bottom bracket 54 configuration, and could be extended to other features, such as an addition or alternative to the top bolts 52. Further, the portion 48B of the AC unit 50 depicted in FIGS. 10-10A is non-limiting. For example, the bottom bracket 54 could be formed around, about, and/or within a different and/or greater or lesser portion of the AC unit 50 permitting the bottom bracket 54 to securely interface the portion and/or the AC unit 50 with the electronics cabinet 100.

FIG. 11 is a front top perspective view of the electronics cabinet 100 with portions of the electronics cabinet 100 depicted with broken lines and solid lines. Ductwork 90 is depicted with solid lines. An entrance orifice 91, depicted as being adjacent to the AC unit 50, may receive air exhausted from the AC unit 50 into the entrance orifices 91. Exit orifice 92 is depicted as being approximately 90 degrees clockwise from the entrance orifices 91, respective to a lateral plane existing approximately vertically centered within ductwork 90, the lateral plane being approximately parallel with floor 1 and roof 24 of the electronics cabinet 100.

FIG. 11A is a front top perspective view of the electronics cabinet 100 with portions of the electronics cabinet 100 depicted with broken lines and solid lines. Edges of the cavity 9 are depicted with solid lines. As previously discussed, cavity 9 is an area of space which may be defined by door 6 (when closed) and electronics rack 10. Cavity 9 may be more or less voluminous depending on any electronic equipment 11′ interfacing with the equipment slots 11″, and depending on depth of damper 80′, which may or may not protrude into the cavity 9.

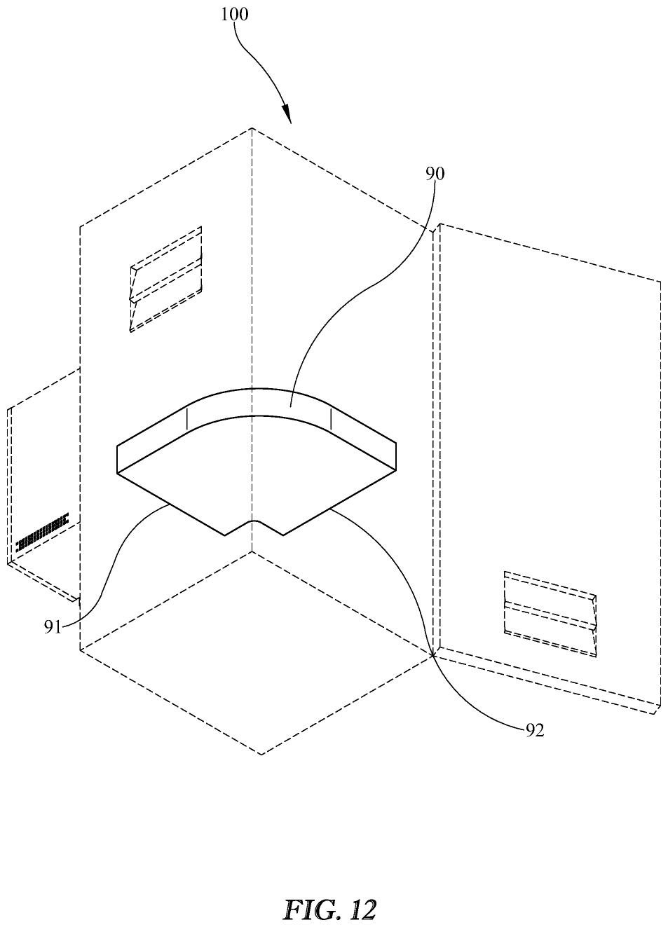

FIG. 12 is a rear bottom perspective view of the electronics cabinet 100 with portions of the electronics cabinet 100 depicted with broken lines and solid lines. FIG. 12 clearly depicts contours and angles that some embodiments of the ductwork 90 may include. However, as discussed previously, the angles and/or contours depicted herein are non-limiting, and the ductwork 90 could include different angles and/or contours depending on factors which would impact operation.

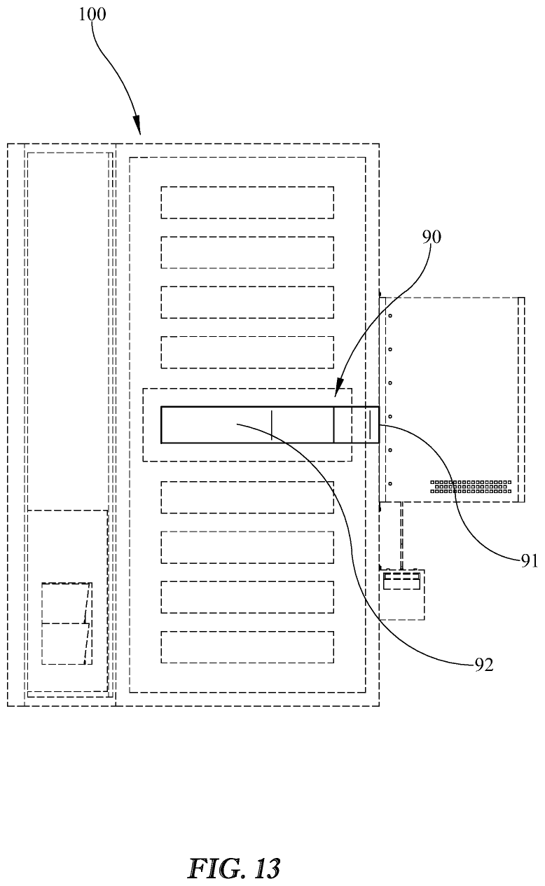

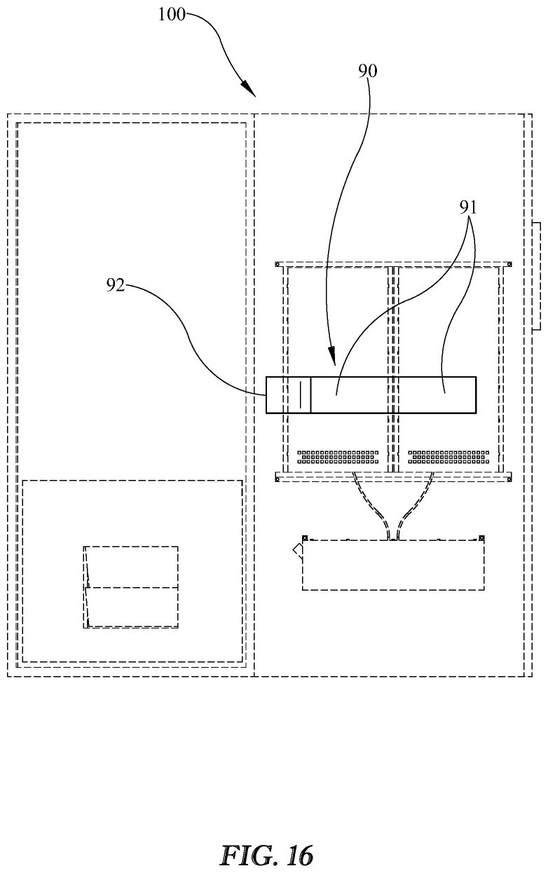

FIGS. 13-16 illustrate front, rear, left, and right direct views, respectively, of the electronics cabinet 100. FIGS. 13-16, like FIGS. 11-12 depict portions of the electronics cabinet 100 with solid lines and broken lines. For example, ductwork 90 is depicted with solid lines and other features of the electronics cabinet 100 are depicted with broken lines. Specifically, FIG. 13 depicts ductwork 90 and the exit orifice 92 from a direct front view. Moreover, FIG. 16 depicts ductwork 90 and the entrance orifices 91 from a direct right view.

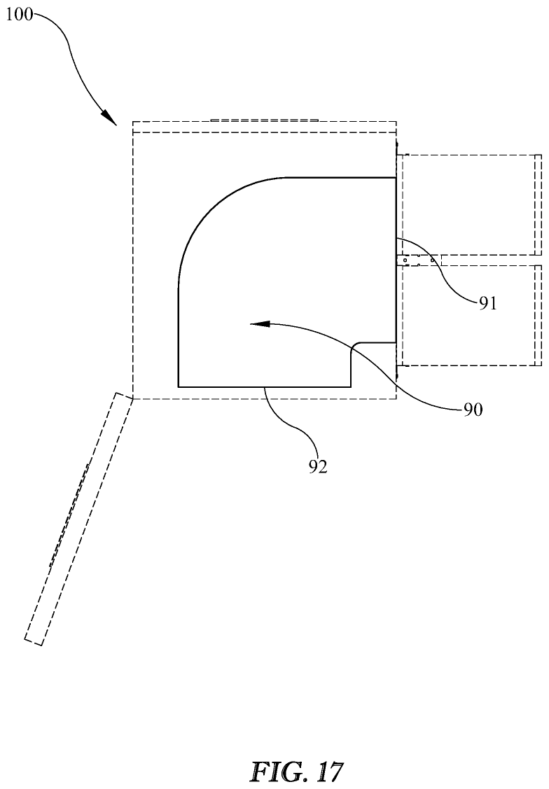

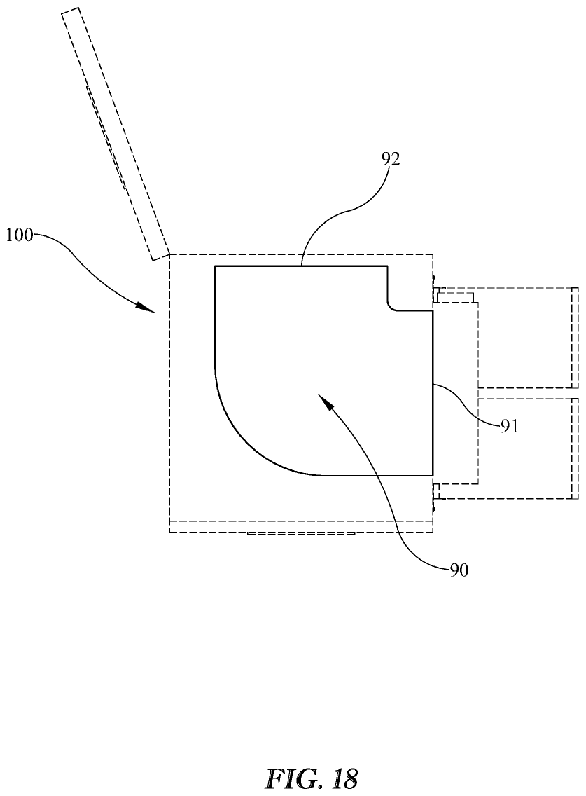

FIGS. 17-18 illustrate top and bottom direct views, respectively, of the electronics cabinet 100. As depicted in FIGS. 17-18, a top-down and bottom-up view of the ductwork 90 may look very similar or identical, aside from reflection symmetries which may be inherent in flipped cross-sectional depictions. In various implementations, ductwork 90 could include features, such as contours, troughs, edges, water lines, and/or holes, which could, for example, aid in condensation dissipation, air circulation, or savings in materials costs. The depictions herein are merely exemplary of some embodiments of features which may be included in the electronics cabinet 100, and should not be construed as limiting the electronics cabinet 100 to the depictions explicitly embodied herein.

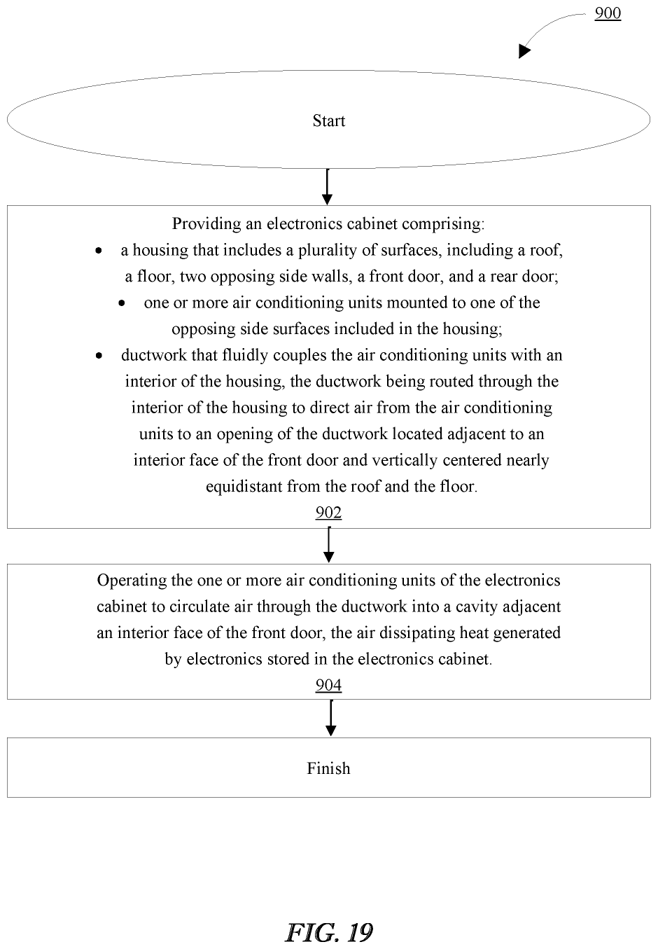

FIG. 19 illustrates a method 900 of producing, providing, and/or operating the electronics cabinet 100.

The method 900 depicted in FIG. 19 begins at block 902 by providing the electronic cabinet 100. The electronic cabinet 100 as depicted in the method of FIG. 19 should comprise: a housing 40 that includes a plurality of surfaces, including a roof 24, a floor 1, two opposing side walls 12′/12″, a front door 6, and a rear door 18. Additionally included are one or more air conditioning units 50 mounted to one of the opposing side surfaces 12′/12″ included in the housing 40. Moreover, included is ductwork 90 that fluidly couples the air conditioning units 50 with an interior 96 of the housing 40, the ductwork 90 being routed through the interior 96 of the housing 40 to direct air from the air conditioning units 50 to an opening of the ductwork 90 located adjacent to an interior face 8 of the front door 6 and vertically centered nearly equidistant from the roof 24 and the floor 1.

The disclosed electronics cabinet 100 may be of a variety of constructions, shapes, sizes, quantities, and positions and still accomplish the same intent. The elements depicted in the figures may not be drawn to scale and thus, the elements may have different sizes and/or configurations other than as shown in the figures.

The method 900 can further include block 904, which comprises operating the one or more air conditioning units 50 of the electronics cabinet 100 to circulate air through the ductwork 90 into a cavity 9 adjacent an interior face 8 of the front door 6, wherein the air dissipates heat generated by electronics 11′ stored in the electronics cabinet 100.

While several embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, embodiments may be practiced otherwise than as specifically described and claimed. Embodiments of the present disclosure are directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

It is to be understood that the embodiments are not limited in its application to the details of construction and the arrangement of components set forth in the description or illustrated in the drawings. The invention is capable of other embodiments and of being practiced or of being carried out in various ways. Unless limited otherwise, the terms “connected,” “coupled,” “in communication with,” and “mounted,” and variations thereof herein are used broadly and encompass direct and indirect connections, couplings, and mountings. In addition, the terms “connected” and “coupled” and variations thereof are not restricted to physical or mechanical connections or couplings.

The foregoing description of several embodiments of the invention has been presented for purposes of illustration. It is not intended to be exhaustive or to limit the invention to the precise steps and/or forms disclosed, and obviously many modifications and variations are possible in light of the above teaching.

What is claimed is:

1. An electronics cabinet comprising:
a housing that includes a plurality of surfaces, including a top surface, a bottom surface, two opposing side surfaces, a front surface, and a rear surface,
a cooling device mounted to one of the opposing side surfaces included in the housing; and
an air distribution conduit that fluidly couples the cooling device with an interior of the housing,
wherein the air distribution conduit is shaped to direct air from the cooling device mounted to the one of the opposing side surfaces to an exit orifice of the air distribution conduit that is located adjacent to an interior face of the front surface.

2. The electronics cabinet of claim 1, further comprising:
an electronics rack extending between the two opposing side surfaces,
the electronics rack being separated from the front surface by a cavity between the front surface and a front surface facing plane of the electronics rack that is parallel with the front surface,
the cavity permitting air expelled from the exit orifice to permeate through the cavity towards the rear and opposing side surfaces.

3. The electronics cabinet of claim 1, wherein the exit orifice is approximately vertically centered between the top surface and the bottom surface.

4. The electronics cabinet of claim 1, further comprising:
a first damper on the front surface permitting air located exterior of the electronics cabinet to convect through the first damper to the interior of the housing; and
a second damper on the back surface permitting air located in the interior of the housing to convect through the second damper to the exterior the electronics cabinet.

5. The electronics cabinet of claim 4, wherein the first damper is located a first distance from the bottom surface, and the second damper is located a second distance from the bottom surface, the second distance being greater than the first distance.

6. The electronics cabinet of claim 4, wherein the first damper and/or the second damper interface with one or more ventilation fans.

7. The electronics cabinet of claim 1, wherein the cooling device detachably interfaces with the one of the opposing side surfaces.

8. The electronics cabinet of claim 7, further comprising:
a bottom L-shaped bracket on the one of the opposing side surfaces, wherein the bottom L-shaped bracket detachably secures the cooling device with one of the opposing side surfaces included in the housing.

9. The electronics cabinet of claim 8, wherein the bottom L-shaped bracket is a French cleat.

10. The electronics cabinet of claim 1, wherein the front and rear surfaces are displaceable doors.

11. The electronics cabinet of claim 1, wherein the exit orifice of the air distribution conduit is approximately horizontally centered between the opposing side surfaces.

12. An electronics cabinet comprising:
a housing that includes a roof, a floor, two opposing side walls, a front door, and a rear door;
one or more air conditioning units mounted to one of the opposing side walls included in the housing;
an electronics rack extending between the two opposing side walls and including one or more slots for receiving electronic equipment; and
ductwork that fluidly couples the one or more air conditioning units with an interior of the housing,
wherein the ductwork is routed through the frame to direct air from the air conditioning units to an opening of the ductwork that empties into a cavity defined between an interior face of the front door and a front door facing plan of the electronics rack, the cavity permitting air expelled from the opening to permeate through the cavity towards the rear door and opposing side walls.

13. The electronics cabinet of claim 12, wherein the opening of the ductwork is vertically centered nearly equidistant from the roof and the floor.

14. The electronics cabinet of claim 12, further comprising:
a first damper on the front door permitting air located exterior of the electronics cabinet to convect through the first damper to the interior of the housing; and
a second damper on the back surface permitting air located in the interior of the housing to convect through the second damper to a the exterior the electronics cabinet.

15. The electronics cabinet of claim 14, wherein the first damper is located a first distance from the floor, and the second damper is located a greater distance from the floor, and wherein the first damper and/or the second damper interface with one or more ventilation fans.

16. The electronics cabinet of claim 15, wherein the first damper convects cooler air exterior the electronics cabinet to a location in the interior of the housing and the second damper convects hotter air in the interior the electronics cabinet to exterior the electronics cabinet.

17. The electronics cabinet of claim 12, further comprising:
a bottom L-shaped bracket, wherein the bottom L-shaped bracket detachably secures the air conditioning units with one of the opposing side walls included in the housing.

18. The electronics cabinet of claim 12, wherein the ductwork is routed along and/or about a 90 degree angle from the side wall to the front door.

19. The electronics cabinet of claim 12, wherein the opening of the ductwork is approximately horizontally centered between the opposing side walls.

20. A method of operating an electronics cabinet, the method comprising:
providing, the electronics cabinet including:
a housing that includes a plurality of surfaces, including a roof, a floor, two opposing side walls, a front door, and a rear door,
one or more air conditioning units mounted to one of the opposing side surfaces included in the housing;
ductwork that fluidly couples the air conditioning units with an interior of the housing,
wherein the ductwork is routed through the interior of the housing to direct air from the air conditioning units to an opening of the ductwork that is located adjacent to an interior face of the front door and is vertically centered nearly equidistant from the roof and the floor; and
operating the one or more air conditioning units of the electronics cabinet to circulate air through the ductwork into a cavity adjacent an interior fact of the front door, the air dissipating heat generated by electronics stored in the electronics cabinet.
